(19) United States
(12) Patent Application Publication
(10) Pub. No.: US 2024/0061341 A1
(43) Pub. Date: Feb. 22, 2024

(54) APPARATUS AND METHOD FOR IMPROVED EXPOSURE OF RELIEF PRECURSORS

(71) Applicant: XSYS GERMANY GMBH, WILLSTATT (DE)

(72) Inventors: Maximilian THATE, Erdmannhausen (DE); Johan VERVAECKE, KORTRIJK (BE); Matthias BEYER, Weinheim (DE)

(73) Assignee: XSYS GERMANY GMBH, WILLSTATT (DE)

(21) Appl. No.: 18/265,876

(22) PCT Filed: Dec. 17, 2021
(86) PCT No.: PCT/EP2021/086474

§ 371 Date: Jun. 7, 2023

(30) Foreign Application Priority Data
Dec. 17, 2020 (NL) 2027144

(51) Int. Cl. G03F 7/20; G03F 7/00

(52) U.S. Cl. CPC G03F 7/2032; G03F 7/201; G03F 7/7005; G03F 7/70525

(57) ABSTRACT

Method for exposing a relief precursor, using a first light source to expose a first side of a relief precursor, a movable second light source to expose a second side of the relief precursor opposite the first side during one or more second exposure periods of one or more second exposure steps, said method comprising the steps of receiving through an operator interface at least one first characteristic representative for the first exposure period and/or at least one second characteristic representative for the one or more second exposure periods determining a sequence of operation for the first light source and the second light source based on the at least one first and/or second characteristic, said sequence being such that each of said one or more second exposure periods either fully overlaps with the first exposure period or does not overlap with the first exposure period.

### FIELD OF INVENTION

The field of the invention relates to apparatus and methods for exposure of relief precursors, in particular printing plate precursors, and more in particular for front and backside exposure of printing plate precursors.

### BACKGROUND

Relief structures can be made by transfer of image information onto an imageable layer and removing parts of the imageable layer. The formed relief may then be used to transfer the information in a printing step onto a substrate. An example of a relief precursor is a printing plate precursor. Digitally imageable flexible printing plate precursors are known, and typically comprise at least a dimensionally stable support layer, a photosensitive layer and a digitally imageable mask layer. The digitally imageable mask layer may be e.g. a laser-ablatable layer. In case of conventional printing plate precursors, the digitally imageable layer is replaced by a separate mask which is attached to a photosensitive layer.

To produce a printing plate from a printing plate relief precursor, according to existing methods, first a mask is written into the digitally imageable layer based on image data to be printed. Following the writing of the mask, the plate is exposed through the mask with radiation such that the photosensitive layer undergoes polymerization or crosslinking or a reaction changing the solubility or fluidity of the photosensitive layer in the regions which are not covered by the mask. Following the exposure, the residues of the mask and of the non-exposed portions of the photosensitive layer are removed. This may be done with one or more liquids in a washer apparatus or by thermal development wherein non-exposed material of the photosensitive layer is liquefied by temperature increase and removed.

Exposure apparatus for printing plate precursors are known. An exposure apparatus may comprise a first light source for back exposure and a second light source for front exposure. Back exposure may be done using a set of UV light tubes or a LED array. The back exposure creates a solid layer (floor) onto which the relief structures are generated. Front exposure may be done using a movable UV light source, such as a movable laser or a LED bar or using stationary light source e.g. an arrangement of tubular light sources. Some exposure apparatus only do front exposure or only do back exposure, depending on the requirements. In some cases the exposure apparatus is capable to expose from both sides and embodiments of the invention relate to such cases.

### SUMMARY

The object of embodiments of the invention is to provide apparatus and methods to expose a relief precursor according to a sequence increasing the productivity, whilst maintaining good results.

According to a first aspect of the invention, a method for exposing a relief precursor is provided, using a first light source configured to expose a first side of a relief precursor during a first exposure period of a first exposure step and a movable second light source configured to expose a second side of the relief precursor opposite the first side during one or more second exposure periods of one or more second exposure steps. The method comprises the steps of receiving through an operator interface at least one first characteristic representative for the first exposure period and/or at least one second characteristic representative for the one or more second exposure periods, determining a sequence of operation for the first light source and the second light source based on the at least one first and/or second characteristic, and exposing the relief precursor according to the determined sequence. The sequence is such that each of the one or more second exposure periods either fully overlaps with the first exposure period or does not overlap with the first exposure period.

In this way an appropriate sequence can be determined based on characteristics entered by an operator. The sequence is determined so that it is avoided that the first light source changes from an exposing state into a non-exposing state whilst the second light source is in an exposing state. In addition, the sequence may include a simultaneous exposure with the first and second light source as long as the second exposure period fully overlaps (i.e. is fully within) the first exposure period. By introducing such a determining step to determine a suitable sequence, the productivity can be increased. Indeed, by introducing overlap where possible without causing a negative impact on the quality of the results, the time needed to perform the method may be shorter.

In a preferred embodiment, the first light source is a back light source for creating a solid layer (floor) at the first side (the back side) of the relief precursor while the second light source is a front light source generating relief structures at the second side (the front side) of the relief precursor.

Thus, according to embodiments of the invention, a front exposure period will always fully overlap with the back exposure period or not at all. In this manner, the thermal behavior of the relief precursor P is controlled during any front exposure (e.g. same front and back exposure conditions during the whole front exposure), ensuring thus the quality of the printing plate, while an overlap—where possible—enables the reduction of the total duration of the exposure method, increasing thus the productivity of the method.

Preferably, both the first and the second characteristics can be changed by an operator and received through the operator interface. In this way, first exposure and second exposure may be customized at will. Alternatively one of the first or second characteristics is preset and the other one is variable and received through the operator interface. In this way, a predetermined number of scenarios may be provided to help the user prior to customization. It is noted that the first and the second characteristics may contain indications for both the first and second exposure period and a first and second non-exposure period of a first and second exposure step, respectively. However, typically first and second non-exposure times will be preprogrammed and not entered by an operator. Also, the first and/or second non-exposure time may be zero or negligible. Alternatively, only the full time period of the first and second exposure step may be provided if the non-exposure period is preprogrammed or negligible.

According to a preferred embodiment, the step of determining a sequence comprises, if the first exposure period is shorter than any one of the second exposure periods of the one or more second exposure steps, selecting a sequential sequence to operate only the first light source or only the second light source at a time. In this way, if the first exposure period is shorter than any second exposure period, an overlap is avoided to prevent first exposure during only part of a second exposure step. In this manner the exposure conditions, e.g. the temperature conditions will be substantially uniform, ensuring in turn a qualitatively good and substantially uniform second exposure step. According to a first option, the first exposure period may precede the at least one second exposure period and according to a second option the first exposure period may follow after the at least one second exposure period. If more than one second exposure step is performed, even more options are possible. Depending on circumstances, one of the three options may be preferred, and the step of determining may optionally take into account further considerations, such as the type of relief precursor, the intensity used, etc. in order to further improve the suitability of the sequence.

According to a preferred embodiment, the step of determining a sequence comprises, if the first exposure period is longer than one of the second exposure periods, selecting that second exposure period for overlapping with the first exposure period. In this way if the first exposure is longer than a second exposure period, second and first exposure may be performed together during that second exposure period, reducing thus the total duration of exposure. According to a first option, the first and second exposure periods may then start together. For some applications, a higher quality is achieved by performing the second exposure as early as possible. For example, the amount of available oxygen may play a role for the second exposure and by doing the second exposure early less oxygen may be present in the relief precursor. Alternatively the first and second exposure periods may end together or the second exposure step selected for overlap may be enclosed in the middle of the first exposure step. Depending on circumstances, one of the three options may be preferred, and the step of determining may optionally take into account further considerations, such as the type of relief precursor, the intensity used, etc in order to further improve the sequence for a desired result.

According to a preferred embodiment, the step of determining a sequence comprises determining for at least one of said one or more second exposure steps whether the second exposure period thereof is smaller than the first exposure period; and if yes, determining the sequence such that the second exposure period of said one second exposure step fully overlaps with the first exposure period; and if no, determining the sequence such that the second exposure period of said one second exposure step does not overlap with the first exposure period. Thus, the step of determining a sequence typically comprises comparing the first exposure period and the one or more second exposure periods of the one or more second exposure steps. In this way, the sequence may be determined simply by comparing directly the durations of the first exposure period and each second exposure period to determine the best sequence for the second and first light sources.

For example, when the one or more second exposure steps comprise a single second exposure step the step of determining a sequence comprises two steps. In a first step the first and second exposure period are compared. In a second step it is determined that the second exposure step is performed such that the second exposure period of said second exposure step fully overlaps with the first exposure period, if the second exposure period is smaller than the first exposure period, or that the second exposure step is performed such that the second exposure period of said second exposure step does not overlap with the first exposure period, if the second exposure period is larger than the first exposure period.

According to a preferred embodiment, during the first exposure period a light intensity emitted by the first light source is substantially constant. In this way the first exposure is performed with a constant intensity, ensuring over time substantially uniform conditions on the relief precursor during the at least one second exposure step.

When referring to a light intensity emitted by the first light source, it is intended to refer to an intensity measured by an Ophir 10A-V1.1 sensor with a 16 mm diameter diaphragm (Ophir Optronics Solutions Ltd) arranged so that the measuring side of the sensor in located in a plane corresponding with the first side of a relief precursor when the relief precursor is arranged in the exposure apparatus. Thus, when the exposure apparatus has a carrying structure with a support surface, e.g. a glass plate with a support surface, the sensor can be placed on the support surface with its measuring side oriented towards the first light source. This is illustrated in FIG. 8, where the sensor S is located on a support surface of a carrying structure 3, e.g. a glass plate, with the measuring side M of the sensor S arranged on the support surface such that the measuring side M receives the light emitted by the first light source.

According to a preferred embodiment, the at least one first characteristic comprises a characteristic representative for the duration of the first exposure period. In this way the duration of the first exposure period can be taken into account when determining the sequence of operation for the second and first light sources. For example, the at least one first characteristic comprises any one of the following or a combination thereof: a duration of the first exposure period, a duration of a first non-exposure period of the first exposure step, a value representative for a light intensity used during the first exposure period. In this way, the conditions of exposure during the first exposure step can be taken into account when determining the sequence of operation for the second and first light sources. It is further noted that a value representative of a light intensity during the first exposure may be correlated to the duration of the first exposure period insofar as both influence a light dose received during the first exposure period. In an example, the first source is a set of UV light tubes provided with a shutter and the non-exposure period may correspond with a time for preconditioning the first light source. In some examples, where an operator enters a value representative for the first exposure period, during the determining it may be determined to increase or decrease the entered first exposure period based on calibration parameters and/or exposure conditions, e.g. based on whether or not a shadow plate is used, see further.

According to a preferred embodiment, the at least one second characteristic comprises at least one characteristic representative for the duration of the one or more second exposure periods. In this way the duration of the one or more second exposure periods can be taken into account when determining the sequence of operation for the second and first light sources. For example, the at least one second characteristic comprises any one of the following or a combination thereof: a speed value for the speed of the movement of the second light source during the one or more second exposure steps, a number of times the same second exposure step is repeated, a duration of a second exposure period of said one or more exposure periods, a duration of a non-exposure period of a second exposure step of said one or more second exposure steps, a value representative for a light intensity used during a second exposure period of the one or more second exposure periods. In particular the speed at which the second light source moves during a second exposure period influences the duration of that second exposure period for a given relief precursor having a given size and can be taken into account for determining the sequence of operation for the second and first light sources. Additionally the number of times the same second exposure step is repeated influences the total duration of the at least one second exposure step and can be taken into account for determining the sequence of operation for the second and first light sources. It is further noted that a value representative of a light intensity may be correlated to a speed value for the movement of the second light source insofar as both influence a light dose received during a second exposure period. Thus, an operator could enter only an intensity value and/or a dose, and a suitable speed (and hence second exposure time) can be determined based thereon by a control means.

When referring to a light intensity emitted by the second light source, it is intended to refer to an intensity between the second light source and a plane corresponding with the first side of a relief precursor when the relief precursor is arranged in the exposure apparatus, at a distance of 15 mm from said plane. Thus, when the exposure apparatus comprises a carrying structure with a support surface, e.g. a glass plate, the intensity is the intensity at a distance of 15 mm above the support surface. However, because the sensor has a certain height and the distance between the second light source and the support surface is typically quite small, the light intensity may have to be measured outside of the exposure apparatus. Thus, the sensor may be arranged outside of the exposure apparatus, but such that the measuring side of the sensor is at a distance dm of the second light source which corresponds with a distance d2 between the second light source and the support surface minus 15 mm (dm=d2-15 mm) Also the intensity of the second light source may be measured by an Ophir 10A-V1.1 sensor with a 16 mm diameter diaphragm (Ophir Optronics Solutions Ltd). This is illustrated in FIG. 8, where the sensor S′ is located such that the measuring side M′ of the sensor S′ is at a distance dm of the second light source 2 which is equal to a distance d2 between the second light source 2 and the support surface of the carrying structure 3 (in the illustrated example d2=50 mm) minus 15 mm, i.e. dm=d2−15 mm=50 mm−15 mm=35 mm.

Note that the distance is measured here between the second light source and the support side of the sensor, and not between the second light source and the measuring side of the sensor. This is illustrated in FIG. 8, where the sensor S is located on a support surface of a carrying structure 3, e.g. a glass plate, with the measuring side M of the sensor S arranged on the support surface such that the measuring side M receives the light emitted by the first light source.

Preferably, the receiving comprises receiving the first exposure period and, for each different second exposure step, a combination of the speed of the movement of the second light source and a number of times the second exposure step is repeated. The one or more second exposure periods may then be derived from the one or more received speed values and corresponding repeat numbers.

According to a preferred embodiment, each second exposure step comprises a second non-exposure period following the second exposure period, and the step of determining takes into account the second non-exposure period. In this way, delays inherent to the exposure process can be taken into account in an exposure step. For instance during the second non-exposure period, time can be provided for moving the second light source first into its initial position after an exposure period.

According to a preferred embodiment, the step of determining is such that the time needed to perform the first exposure step and the one or more second exposure steps is shorter than the time needed to perform the first exposure step and the one or more second exposure steps sequentially.

According to a preferred embodiment, each second exposure step comprises a forward movement and a backward movement. Preferably the second light source exposes the second side during the forward movement during the second exposure period, and the second light source does not expose the second side during the backward movement. In other words, a second exposure step consists of an exposure period corresponding to the forward movement, during which the second light source exposes the relief precursor, and a non-exposure period corresponding to the backward movement, during which the second light source is turned off and merely brought back into its initial position. Alternatively the second light source may expose the second side during both the forward movement and the backward movement, and a first second exposure step will correspond to the forward movement whilst a further second exposure step will correspond to the backward movement. In such an embodiment the non-exposure period during the first and further second exposure step will typically be negligible or very small.

According to a preferred embodiment, the one or more second exposure steps comprise at least two second exposure steps. In this way, a second exposure may be distributed over at least two second exposure steps. Preferably the at least two second exposure steps comprise two different second exposure steps and the step of receiving comprises receiving a second characteristic for each different second exposure step. In this way, the second side of the relief precursor may be exposed sequentially under different conditions, in particular according to a plurality of cycles with stepwise increased or decreased intensities and/or speeds to improve the quality of the edges of the relief structures. For example, one or more cycles with a first intensity and speed may be followed by one or more cycles with a different intensity and/or speed. Alternatively, the at least two exposure steps may be identical, to distribute exposure over time e.g. for thermal reasons (avoiding heat accumulating when exposing during a single cycle at a higher intensity and/or lower speed).

According to a preferred embodiment, the step of determining a sequence comprises the following steps:
comparing the sum of the second exposure periods and an optional intermediate non-exposure period of two second exposure steps with the first exposure period;
if the sum of the second exposure periods and the optional intermediate non-exposure period is smaller than the first exposure period, determining that said two exposure steps are performed such that said two second exposure periods both overlap with the first exposure period; in this way first exposure step can be performed during two consecutive second exposure periods, reducing thus the total duration of the exposure method while ensuring that the first light source remains on during the whole two exposure periods.
if each second exposure period is larger than the first exposure period, determining that said two second exposure steps are performed before and/or after the first exposure step; optionally the first exposure step is performed before the second exposure steps e.g. to favour the quality of the final relief precursor, an already exposed floor layer constituting a good basis for relief structures. Alternatively, the first exposure is performed after the second exposure. In this way, an overlap during only part of any of the second exposure periods is prevented, and a sequential operation is realised ensuring that the first light source will remain off or is shielded during both second exposure periods.
if the second exposure period is smaller than the first exposure period and the sum of the second exposure periods and the optional intermediate non-exposure period is larger than the first exposure period, determining that one of said two second exposure steps is performed such that the second exposure period thereof overlaps with the first exposure period, and another one is performed such that the second exposure period thereof does not overlap with the first exposure period. In this way, an overlap with one whole second exposure period is enabled and an overlap during only part the other second exposure period is prevented.

According to a preferred embodiment, the step of receiving comprises presenting the operator with an operator interface allowing the operator to enter the at least one first and/or second characteristic. In this way, the sequence can be based on customized characteristics entered by an operator to increase the range of applications of the method.

According to a preferred embodiment, the method comprises prior to the step of determining, and optionally prior to the step of receiving, the step of receiving through the operator interface an operation mode out of one or more operation modes. The one or more operation modes comprise at least a first operation mode indicating that the determining step is to be performed to determine the sequence and a second operation mode indicating that a predetermined sequence is to be performed. In this way a user may choose between a predetermined sequence and a sequence calculated to improve the productivity. A predetermined sequence may be a sequence the user has used in the past or a pre-programmed sequence or a sequence entered by an operator.

According to a preferred embodiment, the second operation mode indicates that the one or more second exposure steps need to be performed before the first exposure step, and the one or more operation modes comprise a third operation mode indicating that the one or more second exposure steps need to be performed after the first exposure step. The third mode operation corresponds to a generally preferred mode of operation since an already exposed floor layer is regarded as generally a better basis for relief structures than a non-exposed one. In this way, more flexibility is offered to a user to adapt the exposure method to his needs depending on the circumstances.

According to a preferred embodiment, a movable shield is moved between the first light source and the relief precursor as the second light source is moved. Due to the presence of the moveable shield between the first light source and the relief precursor, the first side of the relief precursor receives less light than without the movable shield. Preferred features of the movable shield, also called shadow plate, can be found in patent application in the Netherlands with application number N2024756 filed on 24 Jan. 2020, which is included herein by reference. For such embodiments, the operator may enter a first exposure period which takes into account that the net dose received will be lower due to the shadow plate, or an operator may enter a value for the first exposure period which does not take into account that the net dose will be lower due to the shadow plate. In the latter case a corrected value for the first exposure period may be determined taking into account the loss due to the shadow plate, and this corrected value may be used for determining the sequence.

According to a preferred embodiment, the first exposure step is performed such that the intensity at the surface of the first side of the precursor, measured as specified above, is in the range of 1 to 200 mW/cm2, preferably 1 to 100 mW/cm2, more preferably in the range of 10 to 50 mW/Cm2; and/or such that a dose at the surface of the first side of the precursor is in the range of 0.01 to 30 J/cm2, preferably in the range of 0.1 to 30 J/cm2, more preferably in the range of 1 to 30 J/cm2.

According to a preferred embodiment, each second exposure step is performed such that the intensity emitted on the second side of the precursor and measured as specified above, is in the range of 20 to 2000 mW/cm2; preferably in the range of 40 to 1000 mW/cm2, more preferably in the range of 50 to 500 mW/cm2 and/or such that a dose at the surface of the second side of the precursor is in the range of 1 to 100 J/cm2, preferably in the range of. 2 to 80 J/cm2, more preferably in the range of 4 to 50 J/cm2.

According to a preferred embodiment, the relief precursor comprises at least a dimensionally stable support, a photoactive layer and optionally a further layer selected from the group comprising a barrier layer, a mask layer (integral or added), a slip layer, an adhesion layer, a protection layer, a functional layer and combinations thereof.

According to a preferred embodiment, the first light source, preferably a stationary light source, comprises a plurality of LEDs or a plurality of light tubes, or a plurality of laser diodes or combinations thereof. Optionally the first light source comprises an intensity control means configured for changing the intensity emitted by the first light source. For example, if the first light source is a LED array, the intensity control means may be a drive means configured to drive the LED array with different power levels. Alternatively, the intensity control means may be an optical means configured vary the light intensity on the relief precursor.

According to a preferred embodiment, the second light source comprises a plurality of LEDs. In this way, a variable intensity may be achieved, in particular for exposing the relief precursor in at least two steps with at least two different intensities. Optionally the second light source comprises an intensity control means configured for changing the intensity emitted by the second light source. For example, if the second light source is a LED array, the intensity control means may be a drive means configured to drive the LED array with different power levels. Alternatively, the intensity control means may be an optical means configured vary the light intensity on the relief precursor. Also, the intensity may be changed by selecting a plate with suitable optical characteristics amongst a plurality of plates with different optical characteristics, and arranging this plate between the second light source and the relief precursor to influence the intensity received by the relief precursor. This plate may be changed when a different intensity is required. In yet another example, a PCB with driver circuitry for generating a required drive current of the second light source may be selected amongst a plurality of PCBs configured for generating different drive current, depending on the required intensity. Also, the distance between the second light source and the relief precursor may be changed to influence the intensity received by the relief precursor. The same methods may be used to change the intensity of the first light source.

According to a preferred embodiment, the illuminated area from the first light source covers an area of 0.5 to 90% of the surface area of the precursor.

According to a preferred embodiment, additional steps are performed in advance to the exposure step comprising any one of the following: removing a protection layer, adding a mask layer, ablating a mask layer, pre-exposing the precursor, and combinations thereof; and/or additional steps are performed after the exposure step which are selected from the group comprising treatment with a liquid, treatment with a gas, thermal treatment, contacting with a surface, removal of material which may be dissolved or liquefied, exposure to electromagnetic radiation, exposure to a plasma, cutting, sanding or combinations thereof.

According to another aspect of the invention, a control means is provided for controlling a first light source configured to expose a first side of a relief precursor during a first exposure period of a first exposure step and a movable second light source configured to expose a second side of the relief precursor opposite the first side during one or more second exposure periods of one or more second exposure steps. The control means is configured to receive through an operator interface at least one first characteristic representative for the first exposure period and/or at least one second characteristic representative for the one or more second exposure periods. The control means is configured to determine a sequence of operation for the first light source and the second light source based on the at least one first and/or second characteristic. The sequence is such that each of the one or more second exposure periods either fully overlaps with the first exposure period or does not overlap with the first exposure period. The control means is configured to control the first and second light source in accordance with the determined sequence.

In this way, according to embodiments of the invention, a second exposure period will always fully overlap with the first exposure period or not at all. In this manner, the relief precursor is ensured to behave substantially uniformly during a second exposure step, ensuring thus the quality of the exposure, while an overlap—where possible—enables the reduction of the total duration of the first and second exposure steps, increasing thus the productivity achieved by the control means.

The control means may be further configured to perform any one or more of the method steps of embodiments of the method disclosed above.

According to a further aspect of the invention, there is provided a computer program comprising computer-executable instructions to perform the method, when the program is run on a computer, according to any one of the steps of any one of the embodiments disclosed above.

According to a further aspect of the invention, there is provided a computer device or other hardware device programmed to perform one or more steps of any one of the embodiments of the method disclosed above. According to another aspect there is provided a data storage device encoding a program in machine-readable and machine-executable form to perform one or more steps of any one of the embodiments of the method disclosed above.

According to a further aspect of the invention, there is provided an exposure apparatus comprising a first light source configured to expose a first side of a relief precursor during a first exposure period of a first exposure step, a movable second light source configured to expose a second side of the relief precursor opposite the first side during one or more second exposure periods (Te2) of one or more second exposure steps, a moving means configured to move the second light source, and a control means according to any one of the embodiments above or a control means storing the computer program of any one of the embodiments above, said control means being configured to control the first light source, the second light source and the moving means in accordance with the determined sequence.

Preferably, the relief precursor is a precursor for an element selected from the group comprising: a flexographic printing plate, a relief printing plate, a letter press plate, an intaglio plate, a (flexible) printed circuit board, an electronic element, a microfluidic element, a micro reactor, a phoretic cell, a photonic crystal and an optical element, a Fresnel lens. To obtain a microfluidic element or a micro reactor an additional layer is added on top of the formed relief, thereby creating channels and spaces.

### BRIEF DESCRIPTION OF THE FIGURES

The accompanying drawings are used to illustrate presently preferred non limiting exemplary embodiments of the apparatus and method of the present invention. The above and other advantages of the features and objects of the invention will become more apparent and the invention will be better understood from the following detailed description when read in conjunction with the accompanying drawings, in which:

FIG. 1 is a schematic sectional view of an exemplary embodiment of an apparatus for exposure of a relief precursor.

FIG. 2 is a perspective view of another exemplary embodiment of an apparatus for exposure of a relief precursor comprising a movable shield.

FIGS. 3A-3F are temporal diagrams of exemplary embodiment of the method for exposure of relief precursor in a case where there is only one second exposure step.

FIGS. 3A-3C illustrate situations where the second exposure period is larger than the first exposure, while FIGS. 3D-3F illustrate situations where the first exposure period is larger than the second exposure.

FIGS. 4A-4F are temporal diagrams of an exemplary embodiment of the method for exposure of relief precursor in a case where there are two second exposure steps.

FIGS. 4A-4C illustrate situations where the second exposure period is larger than the first exposure period, while FIGS. 4D-4E illustrate situations for an overlap during one second exposure step and FIG. 4F illustrates a situation where the first exposure period is larger than the sum of both second exposure periods.

FIG. 5 is a flowchart of an exemplary embodiment of the method for exposure of a relief precursor.

FIG. 6 is another flowchart of another exemplary embodiment of the method for exposure of a relief precursor.

FIG. 7 illustrates a schematic view of an operator interface according to an exemplary embodiment of the invention.

FIG. 8 illustrates schematically how the intensity emitted by the first and second light source is measured.

### DETAILED DESCRIPTION OF EMBODIMENTS

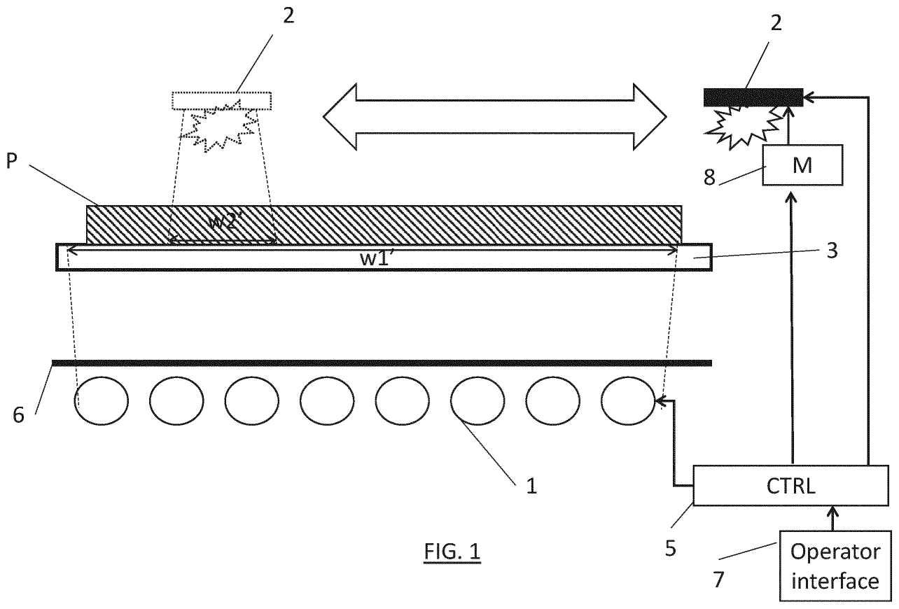

FIG. 1 schematically illustrates an apparatus for exposure of a relief precursor P which comprises a substrate layer and at least one photosensitive layer. The apparatus comprises a first light source 1, a movable second light source 2, and a carrying structure 3. The first light source 1 is configured to illuminate a first side of the relief precursor P, here a lower side also called back side. The movable second light source 2 is configured to illuminate a second side of the relief precursor P, opposite the first side. The second side is typically a top side also called front side of the relief precursor P.

The first light source 1 substantially extends in a plane parallel to the relief precursor P. The first light source 1 is stationary. The second light source 2 is movable back and forward as indicated with arrow A1, in a plane parallel to the plane of the first light source 1.

Preferably, the first light source 1 is configured to illuminate a first illumination area of a plane (having a width w1′ in FIG. 1) and the second light source is configured to illuminate a second illumination area of said plane (having a width w2′ in FIG. 1), wherein said plane is located between the first light source 1 and the second light source 2 and corresponds with a plane in which the first side of the relief precursor is intended to be located. The term illumination area of a plane is defined by the area where the intensity is higher than 10% of a maximum value of the light intensity in said plane. When a carrying structure 3 is present, the plane corresponds with a support surface of the carrying structure 3. Preferably, the second illumination area (having a width w2′ in FIG. 1) is at least two times, more preferably at least three times, and most preferably at least five times smaller than the first illumination area (having a width w1′ in FIG. 1). In typical embodiments, the first light source 1 is used to illuminate substantially the entire first side (i.e. the entire backside) of the relief precursor, whilst the second light source 2 illuminates a smaller area of the second side (i.e. the upper side) of the relief precursor, typically with a higher light intensity. Preferably, the width w2′ is between 100 mm and 600 mm, e.g. between 200 mm and 400 mm. Preferably, the width w1′ is between 1500 mm and 3000 mm, e.g. between 1800 mm and 2500 mm.

The carrying structure 3, e.g. a glass plate, is configured for supporting the relief precursor, and is located between the second light source 2 and the first light source 1. The carrying structure 3 may be transparent to electromagnetic radiation emitted from the first light source 1.

The first light source 1 may be selected from the group comprising: a plurality of LEDs, a set of fluorescent lamps, a flash lamp, a set of light tubes, an LCD screen, a light projection system (with movable mirrors), a sun light collection system, and combinations thereof. The second light source 2 may be selected from the group comprising an LED array, a set of fluorescent lamps, a flash lamp, a set of light tubes arranged in a linear fashion, a (scanning) laser, an LCD screen, a light projection system (with movable mirrors), and combinations thereof. In the example of FIG. 1, the light source 1 is a set of light tubes provided with a shutter 6 which may be open or closed. The shutter 6 may be used to shield the UV light tubes 1 during preconditioning.

FIG. 1 illustrates a moving means 8 configured to move the second light source 2. The control means 5 may control the moving means 8 such that the second light source 2 exposes the whole surface of the relief precursor. The driving of the first and second light source 1, 2 is done by the control means 5 based on information received through an operator interface 7. The control means 5 may be configured for powering the first light source 1 during a first exposure step S1 and for powering and moving the second light source 2 during a second exposure step S2. It is also possible to perform the powering of the second light source 2 according to two or more steps S2, S2′, wherein these steps may be periodic or non periodic. For example after a first exposure step S1 with the first light source 1 and a first second exposure step S2 with the second light source 2, a second or subsequent exposure S2′ with the second light source 2 may be performed. The steps S2 and S2′ may typically be different.

During a first exposure step S1, the first light source 1 may expose the relief precursor P during a first exposure period Te1 and may not expose the relief precursor P during a first non-exposure period Tne1. A first non-exposure period Tne1 may take into account delays inherent to the first exposure process. Typically, when the first source 1 is a set of UV light tubes provided with a shutter, a first non-exposure period Tne1 may comprise a time period for preconditioning the first light source.

During a second exposure step S2 or S2′, the second light source 2 may expose the relief precursor P during a second exposure period Te2 and may not expose the relief precursor P during a second non-exposure period Tne2. A second non-exposure period Tne2 may take into account delays inherent to the second exposure process. Typically the second light source 2 is moved in one direction during a second exposure period Te2 to expose the complete surface of the relief precursor, and moved in the opposite direction, back into its original position, during a non-exposure period Tne2. During a second exposure period the second light source 2 is turned on while during a second non-exposure period the second light source 2 is turned off or shielded.

Based on information received through the operator interface 7, the control means 5 determine a sequence of operation for the first light source 1 and the second light source 2. The control means 5 then control the first light source 1, the second light source 2 and the moving means 8 for exposing the relief precursor P according to the determined sequence. The sequence is such that each of the one or more second exposure periods either fully overlaps with the first exposure period or does not overlap with the first exposure period. The information received through the operator interface 7 may comprise at least one first characteristic representative for the first exposure period Te1 and/or at least one second characteristic representative for the one or more second exposure periods Te2, Te2′.

The at least one second characteristic may comprise any one of the following or a combination thereof: a speed value for the speed of the movement of the second light source 2 during the one or more second exposure steps S2, S2′, a number of times the same second exposure step is repeated, a value representative for a light intensity used during the one or more second exposure periods Te2, Te2′. Typically the second characteristics may comprise for each different second exposure step, a combination of a speed value and a number of repetitions. It is noted that typically also the intensity or power for each second exposure step is entered by an operator, but in most embodiments it is not required to use the intensity or power for determining the sequence. However, in further developed embodiments also the intensity or power may be taken into account.

The at least one first characteristic may comprise any one of the following or a combination thereof: a duration of the first exposure period, a value representative for a light intensity used during the first exposure period Te1. Typically the first characteristic may comprise the duration of the first exposure period. It is noted that also the intensity or power for the first exposure step may be entered by an operator, but in most embodiments it is not required to use the intensity or power for determining the sequence. However, in further developed embodiments also the intensity or power of the first exposure step may be taken into account.

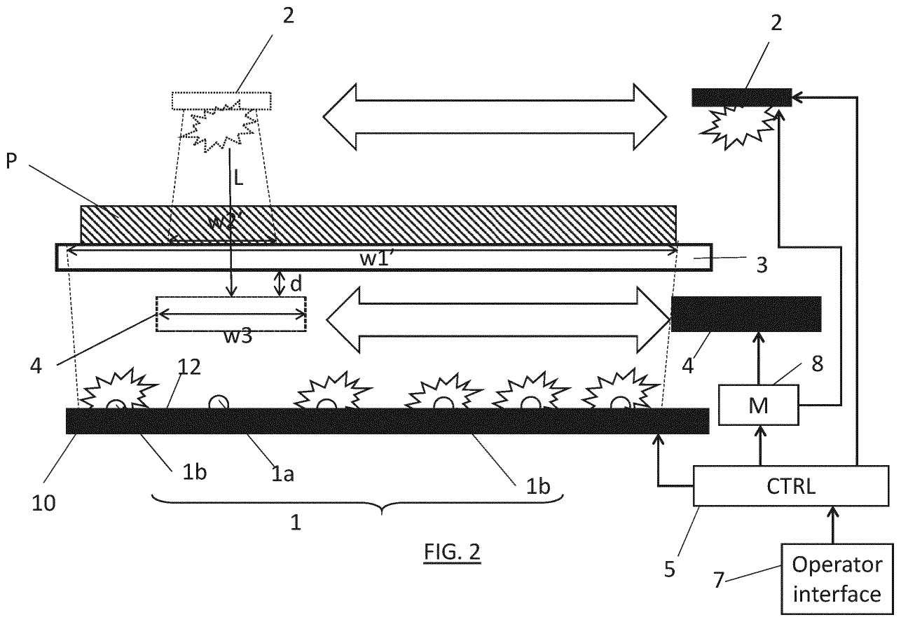

In the embodiment of FIG. 2, in addition to the elements shown in FIG. 1, a movable shield 4 is added. The movable shield 4 is located between the first light source and the second light source 2, and more in particular between the first light source 1 and the carrying structure 3.

The shield 4 is configured to capture at least a portion of the light of the second light source 2 transmitted through the relief precursor P, see arrow L. The shield 4 is non-transparent to electromagnetic radiation emitted from the second light source. The shield 4 has a surface 42, here un upper surface, which is facing the second light source 2 and which is configured to absorb more than 80% of light that is received on said surface, preferably more than 95%. This upper surface 42 may be a black surface. In the illustrated embodiment, the shield 4 is a plate with a flat upper surface 42, but the skilled person understands that the shield may have any suitable shape, and may be e.g. a rod with a black outer surface. The shield 4 may be mechanically coupled to the second light source 2 or may be independently movable. Also the shield 4 is movable back and forward as indicated with arrow A2, in a plane parallel to the plane of the first light source 1. Preferred features of the movable shield can be found in patent application in the Netherlands with application number N2024756 filed on 24 Jan. 2020, which is included herein by reference.

In the embodiment of FIG. 2, the first light source 1 comprises a LED array and the control means 5 may control the first and second light source 1, 2 such that exposure is either simultaneously or sequential, wherein the first light source 1 is controlled such that a group of light emitting elements 1a of the LED array facing the shield are switched off whilst the other light emitting elements 1b of the LED array are switched on, wherein said group 1a is changing as the shield 4 is moved. The first light source 1 comprises a support 10, typically a PCB, having a light absorbing surface 12, e.g. a black surface, facing the second light source 2.

FIG. 2 illustrates a moving means 8 configured to move the movable shield 4 simultaneously with the second light source 2. The control means 5 may control the moving means 8 such that the second light source 2 and the shield 4 move together, and may control the driving of the first light source 1 such that the light distribution of the first light source 1 is adjusted in function of the position of the shield 4.

As in FIG. 1, the driving of the first and second light source 1, 2 is done by a control means 5 based on information received through an operator interface 7. In the embodiment of FIG. 2, the second exposure period may correspond with the duration of the forward movement of the light source 2, and the second non-exposure period Tne2 may correspond to the duration of the backward movement if the second light source 2 is only active during the forward movement and not active during a backward movement.

In the embodiment of FIG. 2, the operator may enter a first exposure period by the first light source 1 which takes into account that the net dose received will be lower due to the movable shield 4, or an operator may enter a value for the first exposure period which does not take into account that the net dose will be lower due to the movable shield 4. In the latter case a corrected value for the first exposure period may be determined taking into account the loss due to the movable shield 4, and this corrected value may be used for determining the sequence.

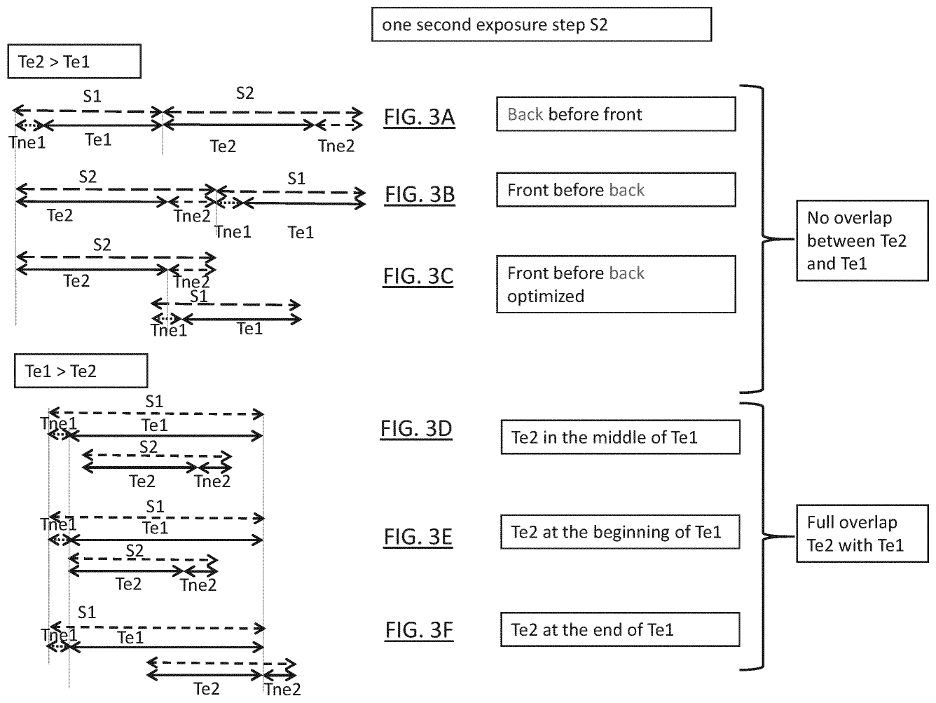

FIGS. 3A-3F are temporal diagrams of an exemplary embodiment of the method for exposure of a relief precursor in a case where there is only one second exposure step S2. Those diagrams mention a first non-exposure period Tne1. Yet, depending on circumstances, a first non-exposure period Tne1 may be zero or negligible. Similarly a second non-exposure period Tne2 may also be zero or negligible, if for instance the second exposure is chosen to be performed during both back and forth movements of the moving means 8.

FIGS. 3A-3C illustrates situations where the second exposure period Te2 is larger than the first exposure period Te1. In order to ensure a substantially uniform second exposure, the first exposure period Te1 and the second exposure period Te2 may not overlap and may have to be performed sequentially to ensure the printing quality of the printing plate. By keeping the first light source 1 turned off during the whole second exposure period Te2, it may be ensured that the relief precursor P may behave in a substantially uniform manner during said second exposure period.

FIG. 3A illustrates a situation where exposing the relief precursor P with the first light source 1 according to a first exposure step S1 may be finished before the exposing of the relief precursor with the second light source 2 according to the second exposure step S2. For example, for thin relief precursors the back-exposure by the first light source 1 may be finished before the main exposure by the second light source 2. The whole duration of the exposure method may then be the sum of the duration of the first exposure step S1 and the second exposure step S2, meaning the sum of the first non-exposure period Tne1, the first exposure period Te1, the second exposure period Te2 and the second non-exposure period Tne2.

FIG. 3B illustrates the alternative situation, where exposing the relief precursor P with the second light source 2 according to a second exposure step S2 may be finished before exposing the relief precursor with the first light source 1 according to the first exposure step S1. For example for thick plates the main exposure by the second light source 2 may be finished before the back-exposure by the first light source 1. The whole duration of the exposure method may then be the sum of the duration of the first exposure step S1 and the second exposure step S2, meaning the sum of the first non-exposure period Tne1, the first exposure period Te1, the second exposure period Te2 and the second non-exposure period Tne2.

FIG. 3C illustrates another alternative situation, where the first exposure step S1 may be started as soon as the second exposure period Te2 may have ended. In this alternative, the first light source 1 may start warming up while the shutter 6 may be closed as soon as the second exposure period Te2 may end. In this situation the first light source 1 may be exposing during the second non-exposure period Tne2, e.g. while the second light source 2 is moved back into its initial position. This alternative may amount to the shortest total duration of all three described situations. The whole duration of the exposure method may then be the sum of the exposure period Te1 and the second exposure period Te2. Also suboptimal solutions are possible where the total duration is e.g. between Te1+Te2 and Te1+Te2+Tne1.

When determining the sequence to be used, one of the options of FIGS. 3A-3C may be chosen, where optionally other factors may be taken into account to determine the preferred option.

Further FIGS. 3D-3F illustrate situations where the first exposure period Te1 is larger than the second exposure period Te2. The first exposure period Te1 and the second exposure period Te2 may then overlap while still ensuring that the relief precursor P may behave thermally in a substantially uniform manner during the second exposure period Te2.

FIG. 3D illustrates a situation where the second exposure period Te2 may be performed in the middle of the first exposure period Te1. In that case the whole duration of the exposure method may then amount to the duration of the first exposure step S1 alone.

FIG. 3E illustrates a situation where the second exposure period Te2 may be started with the first exposure period Te1. Here again the whole duration of the exposure method may then amount to the duration of the first exposure step S1 alone.

FIG. 3F illustrates a situation where the second exposure period Te2 may end with the first exposure period Te1. Here again the whole duration of the exposure method may then amount to the sum of the duration of the first exposure step S1 and the duration of the second non-exposure step Tne2.

When determining the sequence to be used, one of the options of FIGS. 3D-3F may be chosen, where optionally other factors may be taken into account to determine the preferred option.

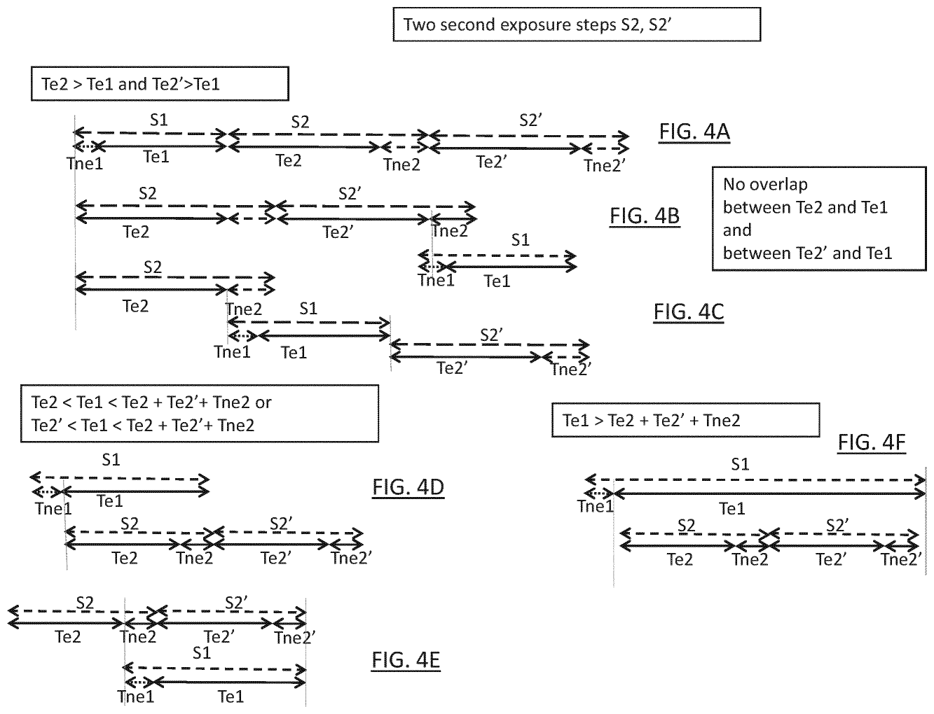

FIGS. 4A-4F are temporal diagrams of exemplary embodiment of the method for exposure of relief precursor in a case where there are two second exposure steps.

FIGS. 4A-4C illustrate situations where the second exposure period is larger than the first exposure, in which case there may be no overlap between Te2 and Te1 nor between Te2′ and Te1. FIGS. 4D-4E illustrate situations for an overlap during one second exposure step S2 or S2′, and FIG. 4F illustrates a situation where the first exposure period may be larger than the sum of both second exposure periods for an overlap during two second exposure steps S2 and S2′.

FIG. 4A illustrates a situation without overlap in which the first exposure step S1, a first second exposure step S2 and a second second exposure step S2′ may be performed consecutively in that order. FIG. 4B illustrates another situation differing from FIG. 4A in that the second exposure steps may be performed before the first exposure step. Besides the first exposure step may be started as soon as the last exposure period Te2′ ends or even slightly before if Tne1 is non-zero, to shorten the sequence. FIG. 4C illustrates another situation wherein the first exposure step is performed between the two second exposure steps and started as soon as the first second exposure period Te2 ends to shorten the sequence. The duration of the sequence in FIGS. 4B and 4C is then identical.

FIG. 4D illustrates a situation where the first exposure period may overlap with the first exposure period Te2 but not with the second exposure period Te2′. The conditions for this situation are that the first exposure period Te1 is bigger than the second exposure period Te2 but smaller than the second exposure period Te2, added to the second exposure period Te2′ and the non-exposure period Tne2. In the example shown, similarly to FIG. 3E, the first and second exposures start together. Yet other alternatives may be envisaged where Te2 may be at the end of Te1 or in the middle of Te1.

FIG. 4E illustrates a situation where the first exposure period may overlap with the first exposure period Te2 but not with the second exposure period Te2′. The conditions for this situation are that the first exposure period Te1 may be bigger than Te2′ but smaller than Te2′ added to Te2 and Tne2. Again, in the example illustrated, similarly to FIG. 3E, the first and second exposures Te1 and Te2′ start together. Yet other alternatives may be envisaged where Te2′ may be at the end of Te1 or in the middle of Te1.

FIG. 4F illustrates a situation where the first exposure period may overlap with both Te2 and Te2′. The condition for this situation is that T1 is bigger than the sum of Te2, Tne2 and Te2′. Again, in the example illustrated, the first and second exposures Te1 and Te2 start together. Yet other alternatives may be envisaged where Te2′ may be at the end of Te1 or Te2 may be in the middle of Te1.

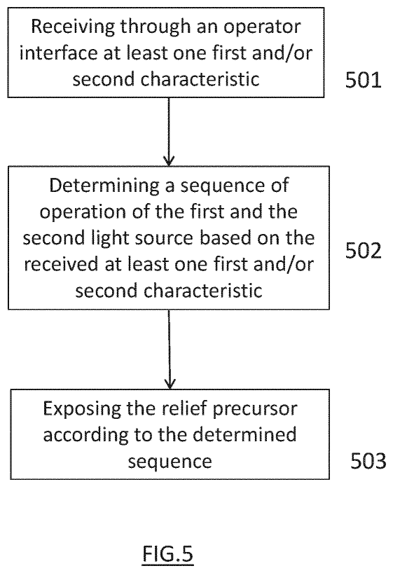

FIG. 5 illustrates a flowchart of an exemplary embodiment of the method for exposure of relief precursor. The method comprises a step 501 of receiving through an operator interface at least first and/or second characteristic.

In a following step 502, a sequence of operation of the first light source 1 and the second light source 2 is determined based on the received at least one first and/or second characteristic. As criteria for the determination of the sequence of operation is primarily the condition that the sequence is such that each of the one or more second exposure periods Te2, Te2′ either fully overlaps with the first exposure period Te1 or does not overlap with the first exposure period Te1.

Additionally, the method may determine the sequence taking into account other criteria including:
the total duration of a sequence of operation to increase productivity;
the sequence of operation with the earliest possible second exposure period; for some relief precursors, the printing quality of the printing plate may decrease with the time separating the first and the second exposure.

In a step 503, the method comprises exposing the relief precursor according to the determined sequence.

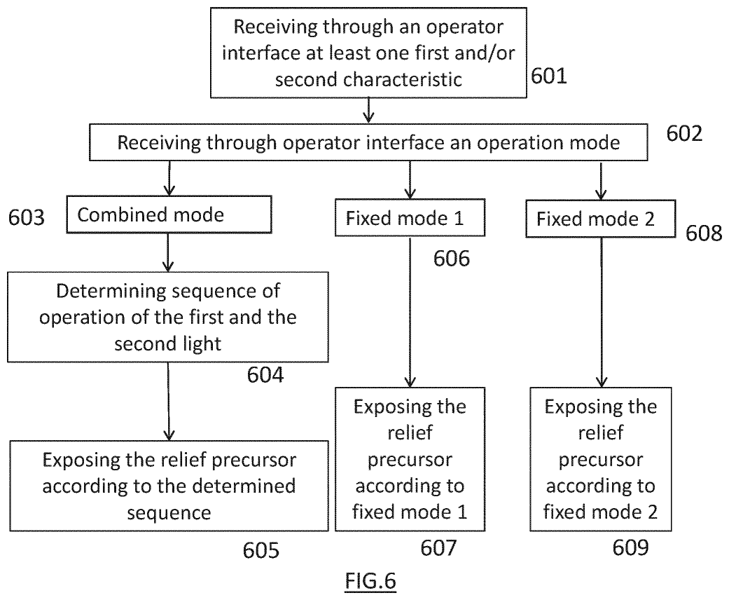

FIG. 6 is another flowchart of another exemplary embodiment of the method for exposure of a relief precursor. In this exemplary embodiment, a mode of operation may further be received through the operator interface during step 602. The step 602 may be performed before or after a step 601 corresponding to step 502 of FIG. 5.

The mode of operation may either be:
a combined mode 603 wherein the control means 5 determines automatically the sequence of operation where the first and the second exposure steps may, depending on circumstances, be overlapped, for an increased productivity, or
a first fixed mode 606 to perform the first exposure step before the at least one second exposure step in a sequential manner,
a second fixed mode 608 to perform the first exposure step after the at least one second exposure step in a sequential manner.

Finally in steps 605, 607 and 608 the relief precursor may be exposed according to the sequence corresponding to the selected mode of operation. In this way an operator may operate his machine with fixed sequences for some types of known relief precursors while he may want to rely on the control means for the determination of a sequence for a new and unknown relief precursor.

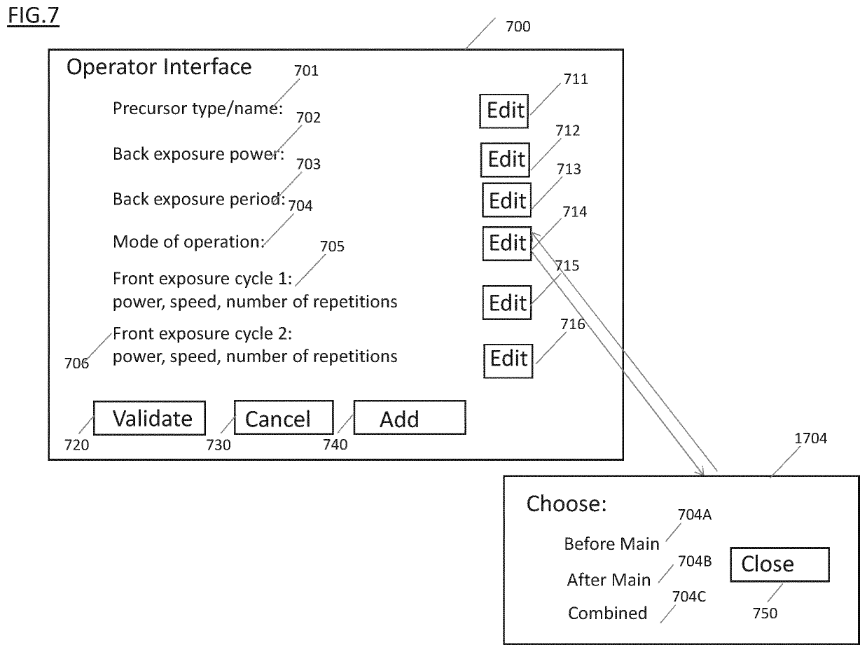

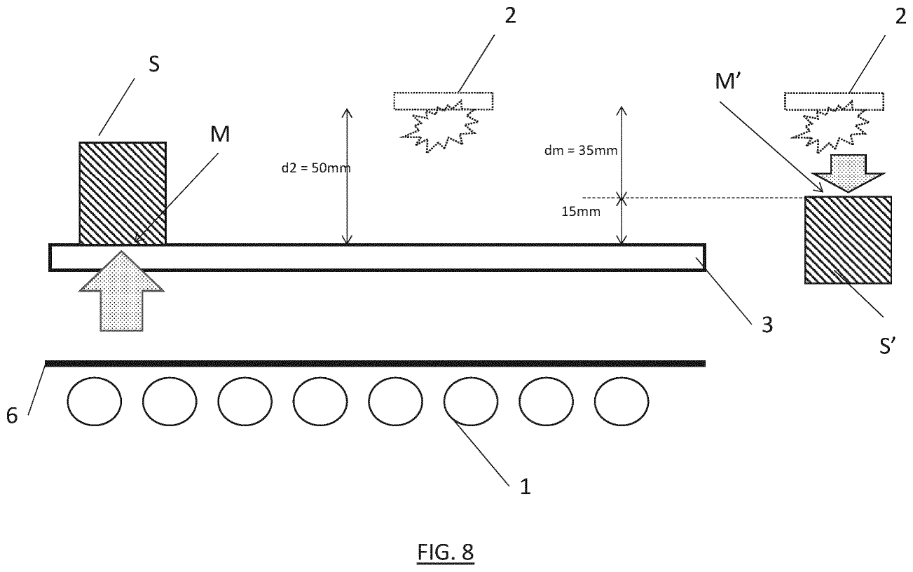

FIG. 7 illustrates a schematic view of an operator interface according to an exemplary embodiment. The operator interface may be a graphical user interface with a window 700, comprising a plurality of editable fields 701-706 and associated buttons 711-716:
a field 701 may be present for the identification of the relief precursor.
fields 702-703 may relate to the first characteristic representative of the first exposure period, here the back exposure period. More in particular, a back exposure power 702 and a back exposure period 703 may be entered or changed.
fields 705 and 706 may relate to the at least one second characteristic representative of the at least one second exposure period, here two cycles of front exposure steps. In the illustrated example second characteristics for two different cycles of second exposure steps can be entered: power, speed and number of repetitions can be entered for a first cycle and for a second cycle. The total number of second exposure steps performed will thus be equal to the sum of the repetition numbers of the first and second cycle.
a field 704 may be present for the mode of operation.

To illustrate the general principle of operation of the graphical user interface, the edition of field 704 will now be described. When activating the button 714 associated with field 704, a new window 1704 may be opened. In the window 1704, an operator may select one of more options 704a-704c corresponding to the available modes of operation, namely in the example ‘Before Main, ‘After Main’ or ‘Combined’. Once a mode is selected, the activation of a button 750 may close the window 1704, returning to the window 700. It is to be understood that windows similar to window 1704 may be opened to edit each of the editable fields 701-703, 705 and 706. A button 720 may be activated to validate all the fields 701-706 to complete the step of receiving information through the operator interface 7. A button 730 may be activated to cancel the edition of the fields 701-706 since the last step of receiving information through the operator interface. A button 740 may be activated to add more editable fields to the window 700. A skilled person would understand that other ways of editing the graphical interface may be envisaged without inventive skill as long as information may be received from an operator.

In non-illustrated embodiments, a post-treatment unit may be provided to perform a post-treatment on the relief precursor, e.g. washing, drying, post-exposure, heating, cooling, removing of material, etc. Further, in non-illustrated embodiments, a pre-treatment unit may be provided to perform a pre-treatment on the relief precursor, said pre-treatment being selected from the group comprising: cutting, ablation, exposure to electromagnetic radiation, and combinations thereof.

A relief precursor generally comprises a support layer and at least one photosensitive layer. The support layer may be a flexible metal, a natural or artificial polymer, paper, ceramic, or combinations thereof. Preferably the support layer is a flexible metal or polymer film or sheet. In case of a flexible metal, the support layer could comprise a thin film, a sieve like structure, a mesh like structure, a woven or non-woven structure or a combination thereof. Steel, copper, nickel or aluminium sheets are preferred and may be about 50 to 1000 μm thick. In case of a polymer film, the film is dimensionally stable but bendable and may be made for example from polyalkylenes, polyesters, polyethylene terephthalate, polybutylene terephthalate, polyamides and polycarbonates, polymers reinforced with woven, nonwoven or layered fibres (e.g. glass fibres, Carbon fibres, polymer fibres) or combinations thereof. Preferably polyethylene and polyester foils are used and their thickness may be in the range of about 100 to 300 μm, preferably in the range of 100 to 200 μm.

A relief precursor may carry at least one additional layer. For example, the additional layer may be any one of the following: a direct engravable layer (for example by laser), a solvent or water developable layer, a thermally developable layer, a photosensitive layer, a cover layer, a barrier layer, a combination of a photosensitive layer and a mask layer. Optionally there may be provided one or more further additional layers on top of additional layer. Between the different layers described above one or more adhesion layers may be located which ensure proper adhesion of the different layers. Such one or more further additional layers may comprise a cover layer at the top of all other layers which is removed before the imageable layer is imaged. The one or more additional layers may comprise a relief layer, and an anti-halation layer between the support layer and the relief layer or at a side of the support layer which is opposite of the relief layer. The one or more additional layers may comprise a relief layer, an imageable layer, and one or more barrier layers between the relief layer and the imageable layer which prevent diffusion of oxygen. Between the different layers described above one or more adhesion layers may be located which ensure proper adhesion of the different layers.

In a preferred embodiment the relief precursor comprises a support layer made of a polyester of polymer material, and an additional layer made of a directly engravable material such as a resin material. The optional layer may then be a laser ablative layer. In an exemplary embodiment the relief precursor may contain at least a dimensionally stable support layer, a relief layer and an imageable mask layer. Optionally, further layers may be present. There may be a cover layer at the top of all other layers which is removed before the imageable mask layer is imaged. There may be an anti-halation layer between the support layer and the relief layer or it may be located at the side of the support layer which is opposite of the relief layer. There may be one or more barrier layers between the relief layer and the imageable mask layer which prevent diffusion of oxygen. Between the different layers described above one or more adhesion layers may be located which ensure proper adhesion of the different layers. One or more layers may be removable by treatment with a liquid. The liquids used may be the same or different for different layers.

In a preferred embodiment the relief precursor comprises a photosensitive layer and a mask layer. The mask layer may be ablated or changed in transparency during the treatment and forms a mask with transparent and non-transparent areas. Optionally the mask layer and/or the barrier layer are removed in the pre-washing section of the system because they may comprise material which could cause problems in further process steps or during use of the final relief. Underneath of transparent areas of the mask the photosensitive layer undergoes a change in solubility and/or fluidity upon irradiation. The change is used to generate the relief by removing parts of the photosensitive layer in one or more subsequent steps. The change in solubility and/or fluidity may be achieved by photo-induced polymerization and/or crosslinking, rendering the irradiated areas less soluble. In other cases the electromagnetic radiation may cause breaking of bonds or cleavage of protective groups rendering the irradiated areas more soluble. Preferably a process using photo-induced crosslinking and/or polymerization is used.

Liquids which may be used to remove material from the exposed precursor include amongst others: Water, aqueous solutions, solvents and combinations thereof. The nature of the liquid used is guided by the nature of the precursor employed. If the layer to be removed is soluble, emulsifiable or dispersible in water or aqueous solutions, water or aqueous solutions might be used. If the layer is soluble, emulsifiable or dispersible in organic solvents or mixtures, organic solvents or mixtures may be used. In the case of organically developable precursors different organic solvents or their mixtures may be used.

Removal of uncured material from the exposed precursor may also be performed by heating and removal of liquefied material with a developing material. The removal of softened material is achieved by continuously contacting it with an absorbing material. The absorbing developer material may be a non-woven of polyamide, polyester, cellulose or inorganic fibres onto which the softened material is adhering and subsequently removed. Such methods are described for example in U.S. Pat. Nos. 3,264,103, 5,175,072, WO 96/14603 or WO 01/88615. Alternatively WO 01/90818 proposed to treat the exposed relief precursor with a hot gas or fluid jet to remove the non-cured material. In EP-A 469 735 and WO 01/18604 devices capable to perform the above mentioned methods are described.

Whilst the principles of the invention have been set out above in connection with specific embodiments, it is to be understood that this description is merely made by way of example and not as a limitation of the scope of protection which is determined by the appended claims.

1. Method for exposing a relief precursor, using a first light source configured to expose a first side of a relief precursor during a first exposure period of a first exposure step, a movable second light source configured to expose a second side of the relief precursor opposite the first side during one or more second exposure periods of one or more second exposure steps, said method comprising the steps of:
receiving through an operator interface at least one first characteristic representative for the first exposure period and/or at least one second characteristic representative for the one or more second exposure periods;
determining a sequence of operation for the first light source and the second light source based on the at least one first and/or second characteristic, said sequence being such that each of said one or more second exposure periods either fully overlaps with the first exposure period or does not overlap with the first exposure period;
exposing the relief precursor according to the determined sequence.

2. The method of claim 1, wherein the step of determining a sequence comprises, if the first exposure period is shorter than any of one of the second exposure periods of the one or more second exposure steps, selecting a sequential sequence to operate only the first light source or only the second light source at a time.

3. The method of claim 1, wherein the step of determining a sequence comprises, if the first exposure period is longer than one of the second exposure periods, selecting said second exposure period for overlapping with the first exposure period.

4. The method of claim 1, wherein the step of determining a sequence comprises:
determining for at least one of said one or more second exposure steps if the second exposure period thereof is smaller than the first exposure period; and
if yes, determining the sequence such that the second exposure period of said one second exposure step fully overlaps with the first exposure period; and
if no, determining the sequence such that the second exposure period of said one second exposure step does not overlap with the first exposure period.

5. The method of claim 1, wherein during each second exposure period which overlaps with a first exposure period, a light intensity emitted by the first light source is substantially constant.

6. The method of claim 1, wherein the at least one first characteristic comprises a characteristic representative for the duration of the first exposure period and/or wherein the at least one second characteristic comprises at least one characteristic representative for the duration of the one or more second exposure periods.

7. (canceled)

8. The method of claim 1, wherein the at least one second characteristic comprises any one of the following or a combination thereof: a speed value for the speed of the movement of the second light source during the one or more second exposure steps, a number of times the same second exposure step is repeated, a duration of a second exposure period of said one or more exposure periods, a duration of a non-exposure period of a second exposure step of said one or more second exposure steps, a value representative for a light intensity used during the one or more second exposure periods; and/or wherein the at least one first characteristic comprises any one of the following or a combination thereof: a duration of the first exposure period, a duration of a non-exposure period of the first exposure step, a value representative for a light intensity used during the first exposure period.

9. (canceled)

10. The method of claim 1, wherein each second exposure step comprises a second non-exposure period following the second exposure period, and wherein the step of determining takes into account the second non-exposure period.

11. The method of claim 1, wherein each second exposure step comprises a forward movement and a backward movement, wherein optionally the second light source exposes the second side during the forward movement during the second exposure period, and wherein the second light source does not expose the second side during the backward movement.

12. (canceled)

13. The method of claim 1, wherein the one or more second exposure steps comprise at least two second exposure steps, wherein optionally the at least two second exposure steps comprise two different second exposure steps and wherein the step of receiving comprises receiving a second characteristic for each different second exposure step.

14. (canceled)

15. The method of claim 13, wherein the step of determining a sequence comprises:
comparing the sum of the second exposure periods and an optional intermediate non-exposure period of two second exposure steps of the at least two exposure steps with the first exposure period;
if the sum of the second exposure periods and the optional intermediate non-exposure period is smaller than the first exposure period, determining that said two exposure steps are performed such that said two second exposure periods both overlap with the first exposure period (Te1>Te2+Te2′+Tne2);
if each second exposure period is larger than the first exposure period, determining that said two second exposure steps are performed before and/or after the first exposure step (Te2>Te1+Te2′+Tne1);
if the second exposure period is smaller than the first exposure period and the sum of the second exposure periods and the optional intermediate non-exposure period is larger than the first exposure period, determining that one of said two second exposure steps is performed such that the second exposure period thereof overlaps with the first exposure period, and another one is performed such that the second exposure period thereof does not overlap with the first exposure period (Te2<Te1<Te2+Te2′+Tne2 or Te2′<Te1<Te2+Te2′+Tne2).

16. The method of claim 1, wherein the step of receiving comprises presenting the operator with an input interface allowing the user to enter the at least one first and/or second characteristic.

17. The method of claim 1, further comprising, prior to the step of determining, and optionally prior to the step of receiving, receiving through the operator interface an operation mode out of one or more operation modes, wherein said one or more operation modes comprise at least a first operation mode indicating that the determining step is to be performed to determine the sequence and a second operation mode indicating that a different predetermined sequence is to be performed; wherein preferably the second operation mode indicates that the one or more second exposure steps need to be performed before the first exposure step, and wherein preferably said one or more operation modes comprise a third operation mode indicating that the one or more second exposure steps need to be performed after the first exposure step.

18. (canceled)

19. The method of claim 1, wherein a movable shield is moved between the first light source and the relief precursor as the second light source is moved.

20. The method of claim 1, wherein the at least one first characteristic comprises a value for the first exposure period which does not take into account that a net dose applied by the first light source will be lower due to the shadow plate, the method further comprising determining a corrected value for the first exposure period taking into account the loss due to the shadow plate, and using this corrected value in the step of determining the sequence.

21. The method of claim 1, wherein the first exposure step is performed such that the intensity at the surface of the first side of the precursor is in the range of 1 to 200 mW/cm2, preferably 1 to 100 mW/cm2; and/or such that a dose at the surface of the first side of the precursor is in the range of 0.01 to 30 J/cm2; and/or wherein each second exposure step is performed such that the intensity emitted on the second side of the precursor is in the range of 20 to 2000 mW/cm2; and/or such that a dose at the surface of the second side of the precursor is in the range of 1 to 100 J/cm2.

22-23. (canceled)

24. The method of claim 1, wherein the first light source, preferably a stationary light source, comprises a plurality of LEDs or a plurality of light tubes, or a plurality of laser diodes or combinations thereof; and/or wherein the second light source comprises a plurality of LEDs, wherein preferably the illuminated area from the first light source covers an area of 0.5 to 90% of the surface area of the precursor.

25-27. (canceled)

28. A control means for controlling a first light source configured to expose a first side of a relief precursor during a first exposure period of a first exposure step and a movable second light source configured to expose a second side of the relief precursor opposite the first side during one or more second exposure periods of one or more second exposure steps, said control means being configured to perform the following steps:
receiving through an operator interface at least one first characteristic representative for the first exposure period and/or at least one second characteristic representative for the one or more second exposure periods (Te2, Te2′);
determining a sequence of operation for the first light source and the second light source based on the at least one first and/or second characteristic, said sequence being such that each of said one or more second exposure periods either fully overlaps with the first exposure period or does not overlap with the first exposure period; and
controlling the first and second light source in accordance with the determined sequence.

29. The control means of claim 28, wherein the step of determining a sequence comprises:
determining for at least one of said one or more second exposure steps if the second exposure period thereof is smaller than the first exposure period; and
if yes, determining the sequence such that the second exposure period of said one second exposure step fully overlaps with the first exposure period; and
if no, determining the sequence such that the second exposure period of said one second exposure step does not overlap with the first exposure period.

30. The control means of claim 28, wherein the step of determining is such that during each second exposure period which overlaps with a first exposure period, a light intensity emitted by the first light source is substantially constant.

31. The control means of claim 28, wherein each second exposure step comprises a second non-exposure period following the second exposure period, and wherein the step of determining takes into account the second non-exposure period.

32. A computer program comprising computer-executable instructions to perform the method, when the program is run on a computer, of claim 1.

33. An exposure apparatus, comprising:
a first light source configured to expose a first side of a relief precursor during a first exposure period of a first exposure step,
a movable second light source configured to expose a second side of the relief precursor opposite the first side during one or more second exposure periods of one or more second exposure steps,
a moving means configured to move the second light source, and
a control means of claim 28, said control means configured to control the first light source, the second light source and the moving means in accordance with the determined sequence, wherein preferably the first light source is a stationary light source.

34-36. (canceled)
